(19) United States
(12) Patent Application Publication
(10) Pub. No.: US 2007/0280847 A1
(43) Pub. Date: Dec. 6, 2007

(54) Preparing and Operating a Vaporizer Body for a Pvd-Metallization System

(76) Inventors: Michael Nurnberger, Schongau (DE); Rudolf Maizinger, Schongau (DE); Ulrich Goetz, Halblech (DE)

Correspondence Address: FAY KAPLUN & MARCIN, LLP, 15O BROADWAY, SUITE 702, NEW YORK, NY, 10038, US

(21) Appl. No.: 11/575,288

(22) PCT Filed: Sep. 16, 2005
(86) PCT No.: PCT/DE05/01631

§ 371 Date: Jul. 27, 2007

(30) Foreign Application Priority Data
Sep. 17, 2004 (DE) 10 2004 045 206.7

(51) Int. Cl. C23C 14/24

(52) U.S. Cl. 419/44; 428/548

(57) ABSTRACT

Preparing and operating a vaporizer body in a PVD-metallization system for continuously supplying and vaporizing metal. A layer structure deposited onto the vaporizer body comprising sinterable powder material in a substantially unsintered state, to which the metal is supplied, is deposited as a raw layer structure onto the vaporizer body and sintered onto the same in the metallization cycle by heating the vaporizer body. The layer structure is consumable during the metallization process and can be replaced directly in the metallization system after each metallization cycle.

The present invention relates to the preparation of a vaporizer body, exemplary of a ceramic vaporizer body, and the operation of the same in a PVD-metallization system, exemplary a metallization system for continuously coating a flexible substrate. On the top side of the vaporizer body a layer structure is placed, which is wettable by the molten mass of metal, and which extends along the vaporizer body being placed with distance to the ends of the same for forming the vaporizing surface of the vaporizer body.

The common method for coating flexible substrates with metals is the so-called vacuum band metallization according to the PVD (physical vapor deposition) technology. For example paper, plastic foils and textiles come into question as flexible substrates, and as metal, mainly aluminium is used. Such coated substrates are widely used for purposes of wrapping and decoration, for the production of capacitors and in environmental technology (insulation).

The flexible substrates are coated in so-called metallization systems. In the metallization system, the substrate to be coated is directed over a cooled roll, and meanwhile exposed to a metal vapor, which condensates on the surface of the substrate as a thin metal layer. For generating the required constant vapor flow, resistance-heated vaporizer bodies are used, exemplary in the form of so-called vaporizer boats, which are heated to approximately 1450-1600° C. by direct current flow. Metal wire is continuously supplied, liquefied on the surface of the vaporizer boat, and vaporized under vacuum at approximately 10⁻⁴ mbar. The mainly used metal is aluminium.

Such vaporizer bodies normally consist of hot-pressed ceramic material, the main component of which is titanium diboride and boron nitride and/or aluminium nitride. In this case, titanium diboride is the electrically conductive component, and boron nitride and/or aluminium nitride the electrically insulating component, which, when mixed together result in specific hot-resistances of 600-6000 μOhm*cm, wherein a mixing ratio of conductive and nonconductive components of respectively 50 weight % (±10 weight %) is provided.

Liquid aluminium causes corrosion and erosion on the vaporizer boat during the metallization process, whereby the usable service life of the vaporizer boat is limited. Washouts of deep trenches in the vicinity of the point where the aluminium wire comes into contact with the vaporizer boat/vaporizing surface and difficulties controlling the optimum temperature distribution across the vaporizing surface during metallization are typical reasons for breakdown. Furthermore, the wetting, and especially the primary wetting of the vaporizer boat with the metal to be vaporized is difficult. The wetting ability of the metal to be vaporized also affects the maximum vaporization rate (kg metal per time unit).

The wetting with copper or silver causes great difficulties due to the unfavourable wetting characteristics of both metals with regard to the titanium diboride-boron nitride-mixed ceramic.

For this reason, prior art refers to a single-layered or multi-layered layer structure which is deposited onto the vaporizer body, onto which the metal is supplied, in order to largely avoid corrosion and erosion of the vaporizer body and to thereby increase the service life of the vaporizer body, and to promote the wettability depending on the metal used. The known layer structures are designed for permanent coating.

It is for example known from DE 195 16 233 C1 to increase the abrasion resistance of the coating of a ceramic or metallic vaporizer body for use in PVD-coating technology by depositing at least one layer of a high-melting boride or carbide or nitride or silicide of the IV., V. and VI. subgroup of the periodic table of the elements, or a stable mixed phase of these compounds, or a stable mixed phase of these compounds with aluminium nitride, and optionally an electrically insulating layer of a high-melting oxide. This coating is deposited by CVD-methods, atomization processes (sputtering processes) or ion plating, and has a total thickness of 12 μm to 45 μm with a structure of three layers. It is also known from DE 25 03 374 to coat a carbon boat for the vaporization of aluminium completely or partially with a protective layer of refractory metals and/or the nitrides of the same, so that the expansion behaviour of the protective layer is compatible with that of the carbon material and the risk of flaking of the protective layer during the vaporization process is reduced. For this purpose, the protective layer is deposited by using a flame or plasma spraying method, or by chemical vapor deposition, wherein the tightest possible adhesion of the protective layer to the carbon substrate is aimed for by previously having roughened the substrate surface.

According to DE 31 14 467 A, it is aimed as well to achieve layers with especially good adhesive properties by providing vaporizer boats of fire resistant oxide ceramic for the vaporization of metals, such as copper, iron, nickel or alloys of these metals, with a coating of tungsten and/or molybdenum. This coating is deposited using the flame-spraying or plasma-spraying method in order to avoid a local flaking, as it is the case with layers which were fabricated of sintered tungsten powder and/or molybdenum powder. With the present invention, a high vaporization rate is achieved in the PVD-metallization by an improved wetting of the vaporizing surface with the respective metal to be vaporized, and it is achieved to increase the endurance of the vaporizer body or vaporizer boat, and to improve electric control of the same, so that the quality of the metal film vapor deposited on the exemplary flexible substrate is increased.

The subject-matter of this invention is exemplary a method for preparing a vaporizer body and operating the same in a PVD-metallization system, wherein a layer structure of at least one layer is deposited onto the vaporizer body for forming the vaporizing surface for the vaporization of the metal, and a metallization cycle is performed, in which the vaporizer body is operated with electric current and is continuously charged with metal, so that the vaporizer body is heated due to its electric resistance, and the metal supplied onto the layer structure is liquefied and vaporized. According to this invention, a layer structure consumable by the operation of the vaporizer body is used as layer structure, which is deposited onto the vaporizer body prior to the metallization cycle as a raw layer structure of sinterable powder material in a substantially unsintered state, and is sintered onto the same in the metallization cycle by heating the vaporizer body.

According to an alternative method of the present invention, the raw layer structure comprises a sinterable powder material in a substantially unsintered state in a low-melting binding material, in which the sinterable powder material is distributed.

In this context, an appropriate granular material of single grains and/or grain agglomerates and/or a granular fraction of presintered material can be used as sinterable powder material. The sintering of the powder material onto the vaporizer body mainly takes place due to the fact that melting bridges are generated between the material structure of the vaporizer body and the grain structure of the powder material, in order to ensure a sufficiently good heat transfer between the vaporizer body and the layer, wherein the melting bridges, if applicable, might be of sintering auxiliary materials and/or of products resulting from a reaction with the metal to be vaporized.

Unlike according to the common methods, the layer structure consisting of one or more layers and deposited for protecting the vaporizer body against erosion in this invention is not designed in favour of a highest possible abrasion resistance and a permanent adhesion to the material of the vaporizer body, but as a so-called sacrificial coating, which is consumed during the metallization process through abrasion caused by erosion and washouts caused by erosion, but until then has a good wettability through the metal liquefied and to be vaporized, and therefore ensures a high and well controllable vaporization rate with a consistent vaporization density.

Since the powder material forming the raw layer structure does not sinter onto the vaporizer body until the vaporizer body is heated and/or sinters onto the vaporizer body during the metallization process, wherein it is also sintered itself, a temporary adhesion of the layer structure to the vaporizer body and among the particles of the layer structure being sufficiently good for the metallization cycle is generated at a simultaneously high wettability and capacity with regard to the metal to be vaporized and at a sufficiently good heat transfer between the vaporizer body and the layer structure. Upon completion of the metallization cycle, the duration of which is determined by the degree of consumption of the layer structure, the consumed layer structure can be removed relatively easily at least partially from the cooled off vaporizer body and be replaced by a fresh raw layer structure at least where the consumed layer structure has come off the vaporizer body by the cooling of the same, whereupon a further metallization cycle might be started. The consumed layer structure is for example removed and replaced in the metallization system without the vaporizer body being dismounted. The vaporizer body as such can therefore be reused in repeated metallization cycles in favour of a long endurance.

It is basically known from DE 25 35 569 A to coat the vaporizing surface of a ceramic vaporizer body coming into contact with the molten metal with a carbide or with tungsten metal, tantalum metal or molybdenum metal, in order to achieve a good wettability of the coating by the molten metal. The coating can be deposited by spraying from the molten mass, in a vaporization coating method or also in a coating drying method. In the latter method, a suspension of powder of the respective carbide or metal in a vaporizable medium is deposited, for example with a brush, and subsequently dried and sintered. The drying shall be performed for example at 60° C. to 200° C., and the sintering should be carried out at 200° C. to 1000° C. However, DE 25 35 569 A does not mention any time, location or quality of sintering. Furthermore, according to the examples it is not a matter of a vaporizer body for a coating for which the supply of the metal to be vaporized takes place continuously. Furthermore, relatively short vaporization cycles of 25 to 322 s are assumed, with good resistance to corrosion of the ceramic material of the vaporizer body.

In contrast thereto, the present invention relates to a method in which the metal to be vaporized is continuously supplied in the form of a wire, wherein the metallization cycle can last 30 to 90 min depending on the material of the layer structure and the height of the vaporization rate.

Although the raw layer structure according to the present invention might be deposited onto a vaporizer body without a cavity, the vaporizer body is provided with a cavity in a further embodiment of the present invention, into which the unsintered powder material forming the raw layer structure is inserted. For example, the cavity has a flat hollow rectangular cross section, which is filled with the powder material up to a remaining cavity having a depth of 0.3 to 3 mm, for example of 0.5 to 0.8 mm, so that spreading of the molten mass is limited.

The raw layer structure might be deposited in a moist state by adding a vaporizable liquid, such as water or ethyl alcohol, to the powder material and, if applicable, in several layers of different powder substances. Such a layer structure is then for example dried under the influence of the vacuum and temperature of the metallization system prior to the heating of the vaporizer body and/or at the beginning of the heating achieved by direct current flow through the vaporizer body. However, in a exemplary embodiment of the invention it is also possible to deposit the raw layer structure onto the vaporizer body in the form of a single-layered or multi-layered prefabricated, for example pressed or also slightly presintered, plate of the powder material. Also in this case, the vaporizer body might be provided with a cavity, into which the plate is inserted.

The layer structure according to the present invention might be composed of a single layer or of several superimposed layers. In the single-layered structure, the sinterable powder material might be provided without or with an additional binding material. Also for the usage of several superimposed layers, sinterable powder materials might be provided in both layers, respectively together with the low-melting binding material or without the low-melting binding material, or the binding material is contained in only one of the layers, exemplary in the upper layer only.

The present invention also allows for providing a relatively thick single-layered or multi-layered layer structure in order to increase the capacity of the same with regard to the liquid metal, and to thereby make it possible to achieve high rates of vaporization. Thus the layer structure according to the present invention might have a total thickness of 0.2 to 1.5 mm, exemplary of 0.6 to 1.0.

While in the prior art it is aimed to adjust the thermal expansion behaviour of a layer structure deposited onto the vaporizer body to the substrate material of the vaporizer body as precisely as possible in favour of a best possible adhesiveness, it can be advantageous according to the present invention to use a layer structure having a thermal expansion coefficient especially at the layer being in contact with the substrate material of the vaporizer body, which is different from the thermal expansion coefficient of the vaporizer body so that detachment and flaking of the layer structure used in the metallization cycle is favoured by the cooling down of the vaporizer body at the end of the metallization cycle. Residues of the layer structure not being detached by the cooling down can generally be easily removed by brushing off or abrading, which also can be done within the metallization system itself.

According to the present invention, a mixed ceramic mainly being composed of TiB₂, BN and/or AlN, or a ceramic-metal-mixture mainly being composed of ZrO₂ and Mo, or a material mainly being composed of carbon is for example used as basic material of the electrically heated vaporizer body and especially of the vaporizer boat.

According to the invention, in the single-layered or multi-layered structure a layer structure for example comprises a layer of a high melting boride or carbide or nitride or silicide of the IV, V and VI subgroup of the periodic table, exemplary titanium diboride, or a stable mixed phase of at least two of these compounds, or a stable mixed phase of at least one of these compounds with aluminium nitride, or molybdenum or tungsten or titanium or zirconium oxide (ZrO₂), the layer laying bare on the top side of the layer structure, and promoting wettability adjusted to the metal to be vaporized. If the layer structure consists of several layers a wetting-inhibiting and/or electrically insulating layer of the group of boron nitride, aluminium nitride, high melting oxides, such as aluminium oxide (Al₂O₃) and yttrium oxide, silicon nitride, aluminium titanate, zirconium silicate, or mixed phases of two or more of these compounds is for example deposited as lowest layer being in contact with the vaporizer body, or as an intermediate layer.

For vaporising aluminium, a single or multi-layer structure comprising a wettable coating for example of a high-melting boride or carbide or nitride or silicide of the IV, V and VI subgroup of the periodic table, exemplary titanium diboride, or a stable mixed phase of at least two of these compounds, or a stable mixed phase of at least one of these compounds with aluminium nitride, or zirconium oxide (ZrO₂) can be used on the vaporizer body. In case of a multi-layer structure where the lowest layer is wetting-inhibiting or insulating, this lowest layer is for example of the group of boron nitride, aluminium nitride, silicon nitride, high melting oxides (such as aluminium oxide (Al₂O₃) or yttrium oxide), aluminium titanate, zirconium silicate, or of a mixed phase of at least two of these compounds.

For vaporizing copper, tin, silver or gold, a single or multi-layer structure is deposited onto the vaporizer body, for example comprising a wettable layer of tungsten, molybdenum or exemplary titanium, or a mixture of these components, wherein in the multi-layer structure a wetting-inhibiting or insulating lowest or intermediate layer exemplary of boron nitride, aluminium nitride, silicon nitride, high melting oxides (such as aluminium oxide (Al₂O₃) or yttrium oxide), aluminium titanate or zirconium silicate, or mixed phases of these compounds.

In the already mentioned variant of the method, where the raw layer structure of a sinterable powder material in a substantially unsintered state is provided in a low-melting binding material, in which the sinterable powder material is distributed, the binding material itself can be provided as a powder material mixed together with the sinterable powder material. Such a mixture can be pressed, especially hot-pressed. However, the binding material can also be fused together with the binding material so that a casting structure is formed by the binding material, into which the sinterable powder material is embedded in an even or uneven distribution.

The low-melting binding material exemplary is a material having a high heat conductivity and is exemplary chosen so that it does not react with the sinterable powder material even in a molten state, and does therefore basically not form any reaction products.

In this variant of the method, the layer containing the low-melting binding material is for example formed as a prefabricated plate.

The binding material is melting during the heating of the vaporizer body, so that the sinterable powder material distributed therein is suspended and sediments so that a good heat contact of the sinter-shaped powder material with the vaporizer body is generated. With an increased heating, the binding material vaporizes completely, without taking an active part in the sintering process.

Tin or bounded tin or a tin alloy is added advantageously as binding material, however, impurities may appear. As an exemplary embodiment tin is advantageous as binding material in this connection, since the interval between its melting point at 230° C. and its vaporization temperature at 1200 to 1400° C. is large, and thus, advantage is taken of the good heat conductivity of the molten tin in favour of a quick and uniform heating of the sinterable powder material for the sintering of the same.

In a second variant of the method, the present invention also relates to a method for preparing a vaporizer body, exemplary a ceramic vaporizer body, and operating the same in a PVD-metallization system, in which method a layer structure of at least two layers is deposited onto the vaporizer body, and a metallization cycle is performed, in which the vaporizer body is operated with electric current and is continuously charged with metal so that the vaporizer body is heated due to its electric resistance and the metal supplied onto the layer structure is liquefied and vaporized. Also in this second variant of the method, a layer structure consumable by the operation of the vaporizer body is used as layer structure, which is deposited onto the vaporizer body prior to the metallization cycle as a raw layer structure comprising an upper layer of a wetting-promoting plate material and a lower electrically insulating and/or wetting-inhibiting layer of sinterable powder material in a substantially unsintered state, and is sintered in the metallization cycle by heating the vaporizer body onto the same.

In this second variant of the method a largely homogeneous plate can be used as upper layer, which is exemplary made of one of the wetting-promoting materials, which are referred to in the other variants of the method described further above, whereas the lower layer is of a wetting-inhibiting and/or electrically insulating powder material of the composition stated for the first variant of the method.

However, it is also possible to form this plate material as a raw layer structure of sinterable but unsintered powder material as well, which can exemplary be provided in tin as binding material.

The above-described features can accordingly be used for the second variant of the method when being adjusted to the usage of a largely homogeneous plate as the upper layer of the layer structure.

In all variants of the method, a multi-layered raw layer structure can be deposited by inserting the lower layer into a cavity of the vaporizer body in a tub-shaped form, and by inserting the upper layer into the tub-shaped lower layer so that the upper layer is surrounded by the lower layer at the lower side and along its perimeter. Hereby, the electric current heating the vaporizer body is to a large extend prevented from also flowing through the layer structure. The present invention also relates to a vaporizer body for operation in a PVD-metallization system, wherein a raw layer structure according to the invention is deposited onto the vaporizer body. Such a vaporizer body precoated with the raw layer structure is for example advantageous for the primary wetting of the same, and can be delivered to customers in a precoated, dried, and, if applicable, presintered state.

The present invention further relates to a sinterable raw layer structure in the form of a prefabricated plate for deposition onto an electrically operable exemplary ceramic vaporizer body for a PVD-metallization system. A single or multi-layered raw layer structure according to the invention of sinterable powder material in a substantially unsintered state or of sinterable powder material in a substantially unsintered state in a low melting binding material, in which the sinterable powder material is distributed, is formed by this prefabricated plate (in the following also referred to as “raw powder plate”).

In an exemplary embodiment of the invention, the prefabricated plate is provided as a layer structure comprising sinterable powder material in a substantially unsintered state in a binding material, as already described above in connection with the first variant of the method. In this connection, tin is for example used as binding material, which can be provided as a powder component in a mixture with the sintering powder and can be pressed, exemplary hot-pressed, with the same thereby forming the prefabricated plate. Advantageously, the tin may be provided as a casting component instead of a powder component, in which the sintering powder is cast in a more or less uniform distribution.

The prefabricated plate is exemplary formed as a single layer plate, wherein the sinterable powder material is a material or material mixture being wetting-promoting for the metal to be vaporized and being composed as described above in connection with the method according to the present invention. However, the prefabricated plate may also have a two-layer structure, in which the lower layer is formed wetting-inhibiting and/or electrically insulating, and deposited (exemplary coated as a suspension) as a thin coating onto the lower side of the upper layer, or onto the lower side and the lateral surfaces of the raw powder-tin-plate.

The plate can for example be formed or cut to size in compliance with the respective vaporizer body, which is provided without or exemplary with a cavity, so that the plate can be directly laid onto the vaporizer body for the first operation of the vaporizer body, or can be laid onto the vaporizer body after the detachment of the layer structure consumed/used in the previous operation for the repeated operation of the vaporizer body.

An exemplary advantage in the usage of tin as binding material for forming the raw powder plate goes back to the fact that tin comprises a very large melting-vaporizing-interval, i.e., tin has a low melting point and a relatively high boiling temperature. Because the boiling temperature of tin is higher than the sintering temperature of the raw powder, the raw powder is provided in suspended form in the molten mass of tin, before and at the beginning of the sintering process. Thereby, an adhesion/holding of the raw powder particles to the vaporizing surface or in the cavity of the vaporizer boat is ensured. Furthermore the raw powder particles are prevented from being prematurely taken away from the vaporizing surface. Furthermore, the molten mass of tin has excellent properties with regard to heat transfer and heat distribution.

In addition, tin is neutral with regard to the sinterable raw powder, i.e., it does not react with the same.

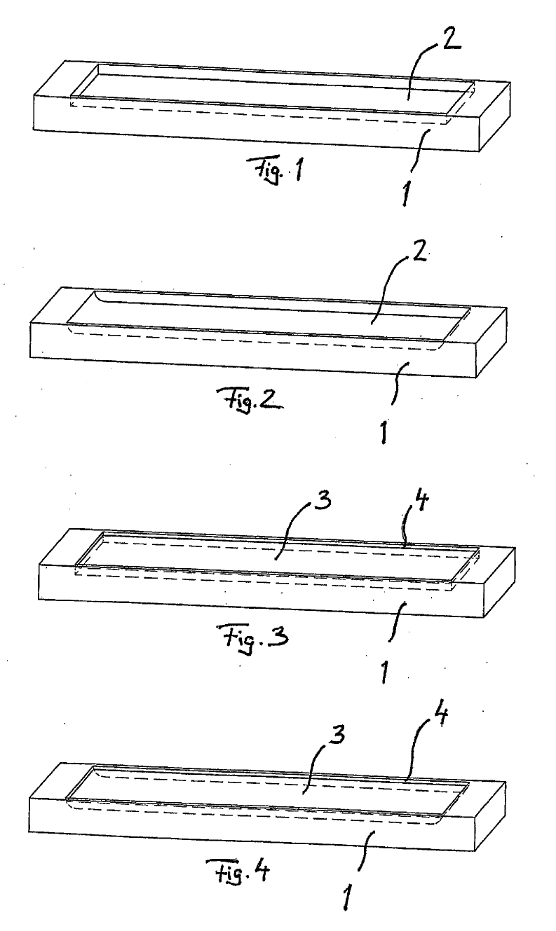

The drawings schematically show exemplary embodiments of a vaporizer body 1 in the form of a typical vaporizer boat having a flat cavity 2 with a hollow rectangular cross section. In the embodiment of FIG. 1, the terminating surfaces of the cavity 2 at both side faces of the same and at the front and back sides of the same, are formed planar and perpendicular to the bottom of the cavity. In contrast, in the embodiment of FIG. 2, the lateral terminating surfaces of the cavity correspond to those of FIG. 1, whereas the front and rear terminating surfaces run obliquely outwards and inclined to the bottom, and are provided with a fillet at the change-over to the bottom. Hereby, mainly scraping or brushing the consumed coating out of the cavity 2 is promoted.

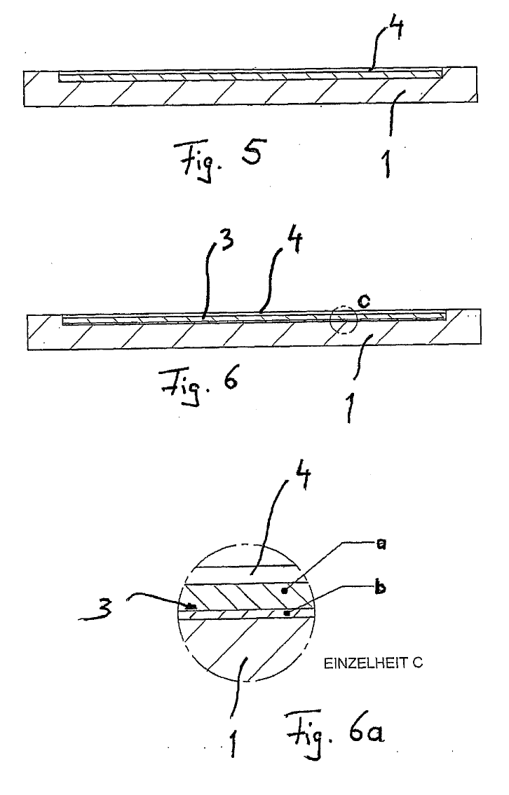

FIGS. 3 and 4 show the embodiments of FIGS. 1 and 2, respectively, comprising a raw layer structure 3 inserted into the cavity. The depth of the respective cavity 2 is adjusted to the thickness of the respective layer structure 3 so that a remaining cavity 4 remains above the layer structure.

The embodiment of FIG. 5 shows a single-layered layer structure 3 inserted into the cavity of the vaporizer body 1, and in the embodiment of FIGS. 6 and 6A, a multi-layer structure 3 having an upper wetting-promoting layer a and a lower wetting-inhibiting and/or electrically insulating layer b is inserted into the cavity of the vaporizer body 1.

### EXAMPLE 1

The trough=cavity of a vaporizer boat, having a depth of 1 mm, a length of 100 mm and a width of 22 mm, wherein the vaporizer boat consists of titanium diboride−boron nitride and has the dimensions 150×30×10 mm (FIG. 1), was provided with the following multi-layer structure (FIG. 6):
a) lower layer b:
   The lower layer b was deposited onto the bottom of the trough (=cavity) of the vaporizer boat with a brush in the form of a thin (approximately 0.1 mm) film of an aqueous suspension of boron nitride powder covering the entire surface of the bottom of the cavity, and was then shortly pre-dried by exposure to air.
b) upper layer a:
   The second layer a was evenly deposited as an aqueous suspension of titanium diboride powder in a thickness of 0.5 mm onto the entire surface of the first boron nitride coating b and was dried by exposure to air and/or later, under the vacuum and temperature influence of the metallization system.

Then, the prepared vaporizer boat was heated in the metallization system under vacuum to a temperature of approximately 1450 to 1600° C. For this, the vaporizer boat comprising the deposited layer structure was heated by conducting electric current through the vaporizer boat.

Then, aluminium wire was continuously supplied onto the heated layer structure.

Result:

The primary wetting of the aluminium on the layer structure is uniform and all over the surface so that the vaporization rate could be increased to more than 1.5 times of that of a comparable, run-in but not coated vaporizer boat. The aluminium vaporized uniformly without local formation of aluminium lakes, i.e., without the formation of splashes, and with a relatively low effort regarding electrical control. The layer structure withstood the corrosive and erosive attacks of the molten mass of aluminium for 30 to 60 minutes, depending on the vaporization rate.

After completion of the metallization of the flexible substrate, the continuous supply of wire was stopped, and the power consumption of the vaporizer boat including the layer structure was maintained for approximately 2 minutes for completely vaporizing the aluminium. Then, the power was put back to 0 kW, which resulted in a rapid cooling down of the vaporizer boat including the layer structure. In most cases, the layer structure completely loosened from the vaporizer boat. The parts of the coating which did come off by the cooling down could be removed without difficulties with a low mechanical force, whereupon the vaporizer boat could be coated again and operated with a comparably good result.

### EXAMPLE 2

### Fabrication and Application of a Plate of Sinterable Powder Material in a Binding Material of Tin

A powder mixture of 70 weight % titanium diboride (d90<50 μm) and 30 weight % tin (d90<60 μm) was dry-mixed in a turbo mixer. This mixture was hot-pressed to a plate of the dimensions height×width×length=0.5×26×100 mm at 300° C. using a heatable press, and was subsequently cooled down in the pressing mold and removed from the mold.

During this pressing process, the tin melted and embedded the sinterable powder. The sinterable powder remained unchanged, i.e., it did not sinter together at these low temperatures and did not form any reaction products with the tin either. During the cooling down, the raw powder-tin-plate was generated.

The plate of sinterable, wetting-promoting powder material (=raw powder) and tin fabricated in such a way has a single layer structure.

This plate of sinterable, wetting-promoting raw powder and tin was put into the cavity of a vaporizer boat consisting of titanium diboride−boron nitrite and having the dimensions 150×30×10 mm and the cavity dimensions 100×26×3 mm (FIG. 1). The vaporizer boat prepared in such a way was then heated up to 1450-1600° C. in the metallization system within ten minutes. For doing so, the vaporizer boat comprising the deposited plate of sinterable, wetting-promoting raw powder and tin was heated by conducting electric current through the vaporizer boat. During the heating process, the tin started to melt at a temperature of approximately 230° C. and a raw powder Sn suspension was generated, which established a good thermal contact to the vaporizer body. At approximately 600° C. the wetting-promoting powder started to sinter in the vicinity of the liquid tin. The liquid tin did not take an active part in the sintering process. The sintering process was completed at approximately 1400° C. Depending on the vacuum in the metallization system, the tin vaporized completely at a temperature of approximately 1200 to 1400° C.

The sintered corrosion-resistant wetting-promoting coating remained, onto which the aluminium wire was then continuously fed.

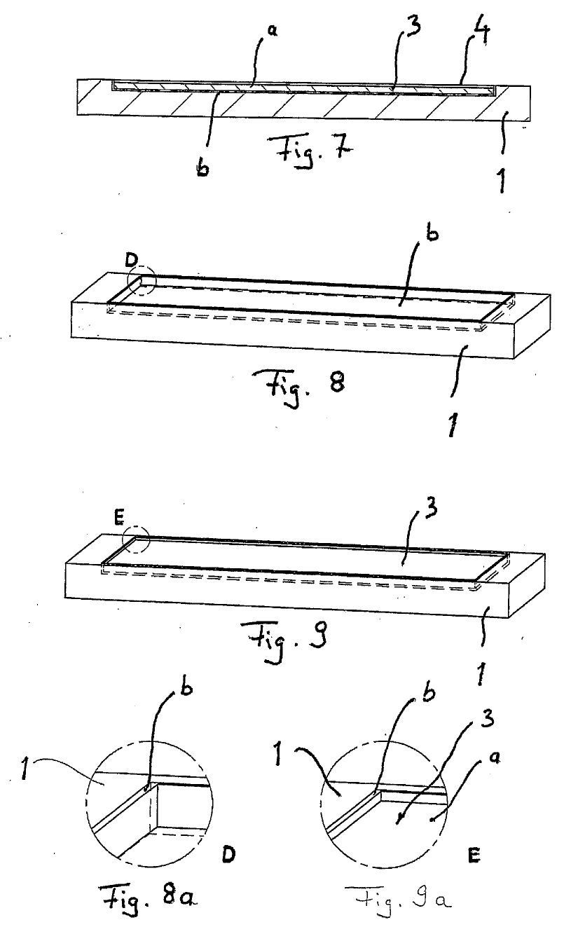

Concentration/thickness of the layers/grain sizes etc.:
concentration of the tin powder in the tin raw powder mixture: 10 to 50 weight % (exemplary 20 to 40 weight %)
grain size of the tin powder: d90=20 to 200 μm (exemplary 40 to 80 μm)
plate thickness: 0.2 to 1.5 mm (exemplary 0.4 to 1.0 mm) In the embodiment shown in FIGS. 7, 9 and 9a, a two-layered layer structure 3 is inserted into the cavity of the vaporizer body 1, comprising, as exemplary shown in FIGS. 7 and 9a, a tub-shaped, wetting-inhibiting and/or electrically insulating layer b all over covering the terminating surface of the cavity, and an upper wetting-promoting layer a, which is received in the tub formed by the tub-shaped layer b. The tub shape of layer b has, especially for an electrically insulating layer material, the advantage that the wetting-promoting layer is also insulated from the terminating wall of the cavity of the vaporizer body 1 at the peripheral sides, whereby electric current is more easily prevented from flowing through the vaporizing material deposited onto the wetting-promoting layer a.

FIGS. 8 and 8a show the vaporizer body 1 during the preparation process with the wetting-inhibiting and/or electrically insulating layer b only being inserted into the cavity in a tub shape at this point of time, onto which the wetting-promoting layer a is then to be deposited.

After deposition of the layer a, a remaining cavity 4 having a terminating surface formed at the peripheral side of the layer b remains as described in the previous examples.

1-34. (canceled)

35. A method for preparing a vaporizer body and operating the vaporizer body in a PVD-metallization system, comprising:
depositing a raw layer structure of at least one layer onto the vaporizer body, the raw layer structure being a prefabricated plate one of (i) a sinterable powder material in a substantially unsintered state and (ii) a sinterable powder material in a substantially unsintered state being distributed in a low melting binding material; and
performing a metallization cycle during which the vaporizer body is operated with an electric current and is continuously charged with metal so that the vaporizer body is heated due to its electric resistance and the metal supplied to the layer structure is vaporized, the raw layer structure being consumable by the vaporizer body to become a consumed layer structure, the raw layer structure being sintered by heating the vaporizer body.

36. The method according to claim 35, wherein the vaporizer body is a ceramic vaporizer body.

37. The method according to claim 35, wherein the depositing step is performed by inserting the plate of powder material into a cavity of the vaporizer body.

38. The method according to claim 37, wherein the cavity is a flat hollow rectangular cross section which is filled with the plate of powder material up to a remaining cavity having a depth between 0.3 and 3 mm.

39. The method according to claim 37, wherein the cavity is a flat hollow rectangular cross section which is filled with the plate of powder material up to a remaining cavity having a depth between 0.5 and 0.8 mm.

40. The method according to claim 35, wherein the raw layer structure consists of several superimposed layers.

41. The method according to claim 40, wherein the raw layer structure comprises (i) an upper wetting-promoting layer including one of (a) the sinterable powder material and (b) the sinterable powder material in low-melting binding material, and (ii) a lower layer including one of (a) a wetting-inhibiting layer and (b) an electrically insulating layer.

42. The method according to claim 35, wherein the raw layer structure has a total thickness between 0.2 and 1.5 mm.

43. The method according to claim 35, wherein the raw layer structure has a total thickness between 0.6 and 1.0 mm.

44. The method according to claim 35, wherein a first thermal expansion coefficient of the raw layer structure is different from a second thermal expansion coefficient of the vaporizer body so that detachment of the consumed layer structure from the vaporizer body is promoted by a cooling down of the vaporizer body.

45. The method according to claim 35, wherein the vaporizer body consists of one of (i) a mixed ceramic having a main component of at least one of TiB2, BN and AIN, (ii) a ceramic metal mixture having a main component of ZrO2 and Mo, and (iii) a material having a main component of carbon.

46. The method according to claim 41, wherein the upper wetting-promoting layer is one of (i) a high melting boride, (ii) a carbide (iii) a nitride, and (iv) a silicide including one of (a) a zirconium oxide, (b) one of a IV, V and VI subgroup, (c) a stable mixed phase of a combination thereof, (d) a stable mixed phase of a combination thereof with aluminium nitride, and (e) one of molybdenum, tungsten, and titanium.

47. The method according to claim 41, wherein one of (a) a lower wetting-inhibiting layer and (b) a lower electrically insulating layer is a powder material comprising one of (i) a boron nitride, (ii) an aluminium nitride, (iii) a silicon nitride, (iv) a high melting oxides, (v) an aluminium titanate, (vi) a zirconium silicate, and (vii) a mixed phase of a combination thereof.

48. The method of claim 46, wherein the metal that is vaporized is one of (i) an aluminium, (ii) a copper, (iii) a tin, (iv) a silver, (v) a gold, (vi) a mixture of a combination thereof, and (vii) an alloy of a combination thereof.

49. The method of claim 47, wherein the metal that is vaporized is one of (i) an aluminium, (ii) a copper, (iii) a tin, (iv) a silver, (v) a gold, (vi) a mixture of a combination thereof, and (vii) an alloy of a combination thereof.

50. The method of claim 35, wherein the low-melting binding material is a tin.

51. The method according to claim 50, wherein the tin is provided as a powder material being one of mixed and pressed with the sinterable powder material.

52. The method according to claim 50, wherein the tin is provided as a casting material comprising the sinterable powder material distributed therein.

53. The method according to claim 47, further comprising:
upon completion of the metallization cycle, removing the consumed layer structure from the cooled-down vaporizer body within the metallization system;
replacing the consumed layer structure with a second raw layer structure for preparing the vaporizer body for a further metallization cycle; and
operating the vaporizer body in the further metallization cycle.

54. The method of claim 41, wherein the raw layer structure is deposited by inserting the lower layer into a cavity of the vaporizer body in a tub-formed shape, and by inserting the upper layer into the tub-formed lower layer, so that the upper layer is surrounded by the lower layer at its lower side and along its perimeter.

55. A method for preparing a vaporizer body and operating the vaporizer body in a PVD-metallization system, comprising:
depositing a raw layer structure of at least one layer onto the vaporizer body, the raw layer structure including an upper layer of a wetting-promoting plate material and a lower layer being one of electrically insulating and wetting-inhibiting of sinterable powder material in a substantially unsintered state; and
performing a metallization cycle in which the vaporizer body is operated with an electric current and is continuously charged with metal so that the vaporizer body is heated due to its electric resistance and the metal supplied to the layer structure is vaporized, the raw layer structure being consumable by the vaporizer body to become a consumed layer structure, the raw layer structure being sintered by heating the vaporizer body.

56. The method of claim 55, wherein the vaporizer body is a ceramic vaporizer body.

57. The method of claim 55, wherein the raw layer structure is deposited by inserting the lower layer into a cavity of the vaporizer body in a tub-formed shape, and by inserting the upper layer into the tub-formed lower layer, so that the upper layer is surrounded by the lower layer at its lower side and along its perimeter.

58. The method according to claim 55, wherein the plate material of the upper layer is formed as a prefabricated plate of a substantially unsintered sinterable powder material as a binding material.

59. The method according to claim 58, wherein the powder material is tin.

60. A prefabricated plate for a PVD-metallization system, comprising:
a sinterable raw layer structure including one of (i) a sinterable powder material in a substantially unsintered state, and (ii) a sinterable powder material in a substantially unsintered state being distributed in a low melting binding material, wherein the raw layer structure is sintered onto a vaporizer body in a metallization cycle by heating the vaporizer body, and is consumable by the vaporizer body.

61. The prefabricated plate according to claim 60, wherein the plate is a layer structure deposited onto the vaporizer body.

62. The prefabricated plate according to claim 61, wherein the vaporizer body is a ceramic vaporizer body.

63. The prefabricated plate according to claim 61, wherein the vaporizer body is electrically operable.

64. The prefabricated plate according to claim 60, wherein the plate is in a pressed, hot-pressed state.

65. The prefabricated plate according to claim 60, wherein the low-melting binding material is tin.

66. The prefabricated plate according to claim 60, wherein the low-melting binding material is a casting material of tin.

67. A method for preparing a vaporizer body and operating the vaporizer body in a PVD-metallization system, comprising:
depositing a raw layer structure of at least one layer onto the vaporizer body, the raw layer structure being a sinterable powder material in a substantially unsintered state being distributed in a low melting binding material of tin; and
performing a metallization cycle in which the vaporizer body is operated with an electric current and is continuously charged with metal so that the vaporizer body is heated due to its electric resistance and the metal supplied to the layer structure is vaporized, the raw layer structure being consumable by the vaporizer body to become a consumed layer structure, the raw layer structure being sintered by heating the vaporizer body.

68. The method according to claim 67, wherein the vaporizer body is a ceramic vaporizer body.

69. The method according to claim 67, wherein the tin is provided as one of (i) a second powder material being one of mixed and pressed with the powder material and (ii) a casting material comprising a sinterable powder material distributed therein.

70. The method according to claim 67, wherein the raw layer structure is deposited as a suspension with an added vaporizable medium.

71. The method according to claim 70, wherein the medium is one of water and ethyl alcohol.

72. The method according to claim 67, wherein the depositing step is performed by inserting the powder material into a cavity of the vaporizer body.

73. The method according to claim 72, wherein the cavity is a flat hollow rectangular cross section being filled with the powder material up to a remaining cavity having a depth between 0.3 and 3 mm.

74. The method according to claim 72, wherein the cavity is a flat hollow rectangular cross section being filled with the powder material up to a remaining cavity having a depth between 0.5 and 0.8 mm.

75. The method according to claim 67, wherein the raw layer structure consists of several superimposed layers.

76. The method according to claim 67, wherein wherein the raw layer structure comprises (i) an upper wetting-promoting layer including one of (a) the sinterable powder material and (b) the sinterable powder material in low-melting binding material, and (ii) a lower layer including one of (a) a wetting-inhibiting layer and (b) an electrically insulating layer.

77. The method according to claim 67, wherein a first thermal expansion coefficient of the raw layer structure is different from a second thermal expansion coefficient of the vaporizer body so that detachment of the consumed layer structure from the vaporizer body is promoted by a cooling down of the vaporizer body.

78. The method according to claim 75, wherein the several superimposed layers include (i) an upper wetting-promoting layer of the sinterable powder material in low-melting binding material of tin and (ii) a lower layer including one of (a) wetting-inhibiting and (b) electrically insulating.

79. The method of claim 78, wherein the raw layer structure is deposited by inserting the lower layer into a cavity of the vaporizer body in a tub-formed shape, and by inserting the upper layer into the tub-formed lower layer, so that the upper layer is surrounded by the lower layer at its lower side and along its perimeter.

80. The method according to claim 67, further comprising:
upon completion of the metallization cycle, removing the consumed layer structure from a cooled-down vaporizer body within the metallization system;
replacing the consumed layer structure by a second raw layer structure for preparing the vaporizer body for a further metallization cycle; and
operating the vaporizer body in further second metallization cycle.
